(19) United States
(12) Patent Application Publication
(10) Pub. No.: US 2010/0285631 A1
(43) Pub. Date: Nov. 11, 2010

(54) METHOD OF SELECTIVELY DOPING A SEMICONDUCTOR MATERIAL FOR FABRICATING A SOLAR CELL

(75) Inventors: Michelle McCann, Cook (AU); Peter Fath, Konstanz (DE)

Correspondence Address: GANZ LAW, P.C., P O BOX 2200, HILLSBORO, OR, 97123, US

(73) Assignee: BLUE HIMMEL SOLAR PTY LTD, Acton (AU)

(21) Appl. No.: 12/810,191

(22) PCT Filed: Dec. 24, 2008
(86) PCT No.: PCT/AU08/01912

§ 371 Date: Jul. 15, 2010

(30) Foreign Application Priority Data
Jan. 2, 2008 (AU) 2008900013

(51) Int. Cl. H01L 31/18

(52) U.S. Cl. 438/98; 438/72; 257/E31.11

(57) ABSTRACT

The present disclosure provides a method of selectively doping a semiconductor material for fabricating a solar cell. The method comprises forming at least one angled groove in the semiconductor material and forming a diffusion barrier on the semiconductor material. The diffusion barrier comprises a diffusion barrier material that is selected so that diffusing of a dopant material through the diffusion barrier is reduced. The method also comprises doping the semiconductor material by exposing the semiconductor material to the dopant material in a manner such that a region of the semiconductor material that is covered by the diffusion barrier has a predetermined first dopant concentration. In addition, the method comprises forming an electrical contact within the at least one angled groove after exposing the semiconductor material to the dopant material. The method is conducted so that a surface area of the semiconductor material within the at least one groove is substantially free from diffusion barrier material and has a second dopant concentration that is higher than the first dopant concentration.

### FIELD OF THE INVENTION

The present invention broadly relates to a method of selectively doping a semiconductor material for fabricating a solar cell.

### BACKGROUND OF THE INVENTION

Solar cells are being produced in large numbers and presently gain importance as means for generating electrical energy in a convenient and largely environmentally friendly way. Solar cells typically comprise doped silicon wafers and are arranged to absorb photons. The photon absorption generates electron-hole pairs, which are separated by p-n junctions. It would be beneficial if the efficiency with which light can be converted into electrical energy can be increased and the cost of producing a solar cell can be reduced. The present invention provides technological advancement.

### SUMMARY OF THE INVENTION

The present invention provides a method of selectively doping a semiconductor material for fabricating a solar cell, the method comprising the steps of:
forming at least one angled groove in the semiconductor material;
forming a diffusion barrier on the semiconductor material, the diffusion barrier comprising a diffusion barrier material that is selected so that diffusing of a dopant material through the diffusion barrier is reduced; and thereafter
doping the semiconductor material by exposing the semiconductor material with the at least one groove to the dopant material in a manner such that a region of the semiconductor material that is covered by the diffusion barrier has a predetermined first dopant concentration; and thereafter
forming an electrical contact within the at least one angled groove;
wherein the method is conducted so that at least a portion of a surface area of the semiconductor material within the at least one groove and below the electrical contact has a second dopant concentration that is higher than the first dopant concentration.

The step of doping the semiconductor material with the at least one groove typically is conducted so that a selective emitter is formed in a single doping step, which has the advantage that fabrication of the solar cell is simplified.

The at least one angled groove typically is sufficiently angled and the electrical contact typically is arranged so that at least a portion of the electrical contact is hidden by a portion of the semiconductor material, which has the advantage that an active area of the solar cell, which is arranged for receiving light and generating electron hole pairs, is increased.

The at least one angled groove typically is formed so that, prior to forming the electrical contact, the semiconductor material overhangs a portion of the at least one groove, such as the majority of the surface area of the groove. The diffusion barrier typically is formed using a suitable directional deposition process conducted so that a relatively large area of the at least one groove is substantially free of the diffusion barrier material. This has the advantage that a relatively large area of the at least one groove may have the higher dopant concentration, which in turn has advantages for reducing the electrical resistance between the semiconductor material and the electrical contact.

An edge of the at least one groove may overhang an entire bottom portion of the at least one groove.

The method may also comprise forming a layer of an electrically insulating material, such as silicon nitride, on the semiconductor material in a manner such that a portion of the surface area of the semiconductor material within the at least one angled groove is substantially free from the electrically insulating material. The layer of the electrically insulating material typically also has anti-reflective and/or surface passivating properties. The step of forming the layer of an electrically insulating material typically comprises forming the layer by a directional deposition process.

The step of forming the electrical contact typically comprises forming the electrical contact at that surface area at which the at least one angled groove is substantially free of the electrically insulating material. The electrically insulating material may be formed using any suitable process, such as a suitable directional deposition process including selected forms of physical and chemical vapour deposition and plasma enhanced chemical vapour deposition (PECVD).

The step of forming at least one angled groove typically comprises forming a plurality of angled grooves, such as a plurality of parallel grooves.

The semiconductor material typically is silicon and may be provided in the form of a substantially single crystalline or polycrystalline silicon wafer. The dopant material typically comprises phosphorous or boron.

The step of doping the semiconductor material typically comprises exposing the semiconductor material with the diffusion barrier to a fluid, such as a liquid or a gaseous medium that comprises the dopant material.

The step of forming the at least one groove may comprise cutting, sawing, laser ablation, electron beam ablation or any other suitable process.

In a first specific embodiment of the present invention the at least one angled groove is formed after formation of the diffusion barrier so that the at least one angled groove cuts through the diffusion barrier and consequently a surface area of the semiconductor material within the at least one groove is then substantially free from the diffusion barrier material.

The diffusion barrier may comprise any suitable material, such a silicon dioxide, amorphous silicon or silicon nitride. The diffusion barrier may be formed using any suitable directional or non-directional formation process, such as thermal oxidation, physical or chemical vapour deposition including PECVD and low pressure chemical vapour deposition (LPCVD).

In the first specific embodiment the diffusion barrier may then be removed after doping and a layer of an electrically insulating material, such as silicon nitride, may then be formed on the semiconductor material in a manner such that a portion of the surface area of the semiconductor material within the at least one angled groove is substantially free from the electrically insulating material. Alternatively, the diffusion barrier may not be removed and the layer of the electrically insulating material may be deposited over the diffusion barrier. As the at least one groove is formed after the diffusion barrier, a surface of the at least one groove is substantially free from diffusion barrier material and has a second dopant concentration that is higher than the first dopant concentration.

In second specific embodiment of the present invention the at least one angled groove is formed prior to the diffusion barrier. In this embodiment the diffusion barrier typically is formed using a directional deposition process. The diffusion barrier may comprise any suitable material that can be formed using a directional formation process. For example, the diffusion barrier may comprise silicon dioxide, amorphous silicon or silicon nitride that may be formed using a directional deposition process, such selected forms of physical or chemical vapour deposition including PECVD. The at least one angled groove is shaped and the doping is conducted so that a portion of the surface area of the semiconductor material within the at least one angled groove is substantially free from diffusion barrier material and has a second dopant concentration that is higher than the first dopant concentration.

In one variation of the second specific embodiment of the present invention, the diffusion barrier material may be selected to provide desired anti-reflective and/or surface passivating properties so that there is no need for depositing an additional layer having such properties, which further improves the production efficiency.

In an alternative variation of the second specific embodiment of the present invention the diffusion barrier is removed after doping and an electrically insulating and typically anti-reflective and/or surface passivating layer is formed on the semiconductor material in a manner such that a portion of the surface area of the semiconductor material within the at least one angled groove is substantially free from the electrically insulating material. Alternatively, the electrically insulating layer is formed over the diffusion barrier.

The invention will be more fully understood from the following description of specific embodiments of the invention. The description is provided with reference to the accompanying drawings.

### BRIEF DESCRIPTION OF THE DRAWINGS

FIG. 1 (a)-(e) illustrate processing steps of a method of selectively doping of a semiconductor material for fabricating a solar cell according to a first specific embodiment of the present invention and

FIG. 2 (a)-(d) illustrate processing steps of a method of selectively doping of a semiconductor material for fabricating a solar cell according to a second specific embodiment of the present invention.

### DETAILED DESCRIPTION OF SPECIFIC EMBODIMENTS

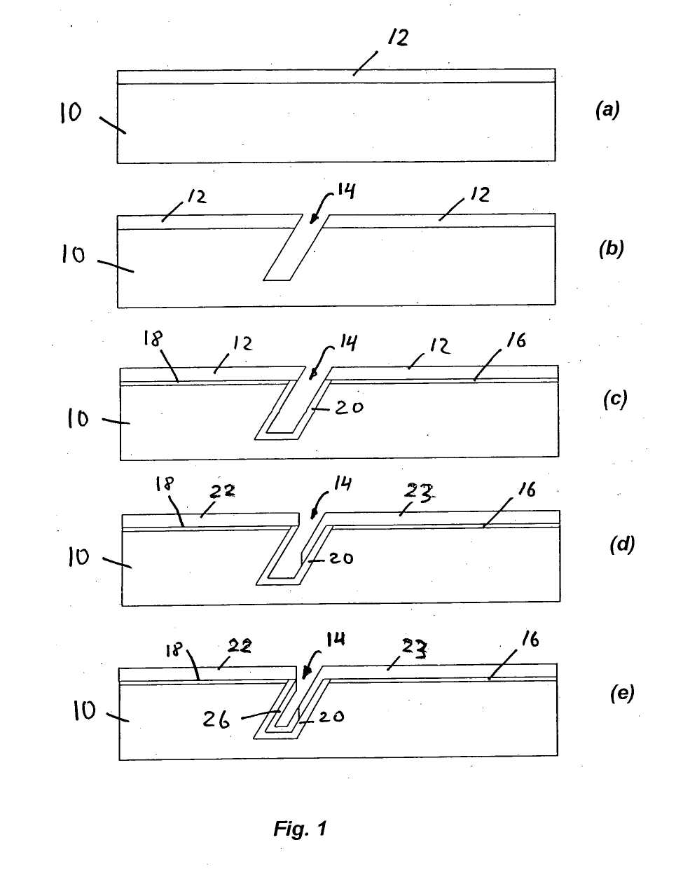

Referring initially to FIG. 1, a method of selectively doping a semiconductor material for fabrication a solar cell is now described. FIG. 1 (a) shows a substrate of a semiconductor material 10, which in this embodiment is provided in the form of a silicon wafer. The silicon wafer is coated with a diffusion barrier layer 12 which is composed of silicon nitride, silicon dioxide, amorphous silicon or any other suitable material. Silicon dioxide may for example be formed by thermal oxidation of the semiconductor substrate 10. Layers of amorphous silicon or silicon nitride may be formed using any suitable deposition techniques, including physical and chemical vapour deposition such as low pressure chemical vapour deposition (LPCVD) and plasma enhanced chemical vapour deposition (PECVD). The thickness of the diffusion barrier 12 is selected so that in a subsequent doping process the diffusion of dopant material into surface regions of the semiconductor material 10 is reduced, but not inhibited.

FIG. 1 (b) shows the semiconductor material 10 with the diffusion barrier 12 and an angled groove 14 that was cut through the diffusion barrier 12 and into the semiconductor material 10. The angled groove may be cut by mechanically sawing, an electron beam, laser ablation or any other suitable process.

Details of the processes that are used for forming the angled groove 14 and properties of the angled groove 14 are disclosed in German patent application DE 10 2005 022139, which is hereby incorporated by cross-reference (which is not an admission that DE 10 205 022139 forms a part of the common general knowledge).

FIG. 1 (c) shows the semiconductor material 10 of FIG. 1 (b) after exposure to a dopant material. Doping was effected so that a selective emitter is formed in a single doping step. An internal surface region 20 of the angled groove 14 is substantially free from diffusion barrier material and is heavily doped. Further, regions 16 and 18, which are positioned below the diffusion barrier 12, are lightly doped.

Doping may be effected by exposing the semiconductor material 10 to a fluid, such as a gas or liquid that comprises the dopant material. For example, the dopant material may comprise boron or phosphorus and a person skilled in the art will appreciate that any suitable known doping procedure may be used.

The diffusion barrier 12 typically is then removed after doping using suitable etching procedures. However, especially if the diffusion barrier comprises silicon nitride, removal of the diffusion barrier 12 may not necessarily be required.

An electrically insulating, anti-reflective and surface passivating layer, in this example composed of silicon nitride, is then deposited onto the doped surface of the semiconductor substrate 10. FIG. 1 (d) shows the deposited silicon nitride layer portions 22 and 23. The silicon nitride layer portions 22 and 23 are deposited using a directional deposition technique, such as PECVD. The groove 14 is sufficiently deep, narrow and angled at an angle that is sufficient so that the directional deposition process of the silicon nitride layer portions 22 and 23 only coats a small portion of the interior surface of the groove 14.

A metallic layer 26 is then formed selectively only at the interior surface portions of the groove 14 that are not coated by the silicon nitride layer 22. For example, the layer 26 may be formed using an electroless plating or electro-plating process that deposits nickel, copper and silver on areas that are not covered by the silicon nitride material.

The method according to the above-described first specific embodiment of the present invention combines the advantages that only a single doping step is required for selective doping and thereby forming a selective emitter in a manner such that low electrical resistance between the semiconductor material and the electrical contacts is facilitated and the electrical contacts of the semiconductor material 10 are hidden, which increases the efficiency of a formed solar cell.

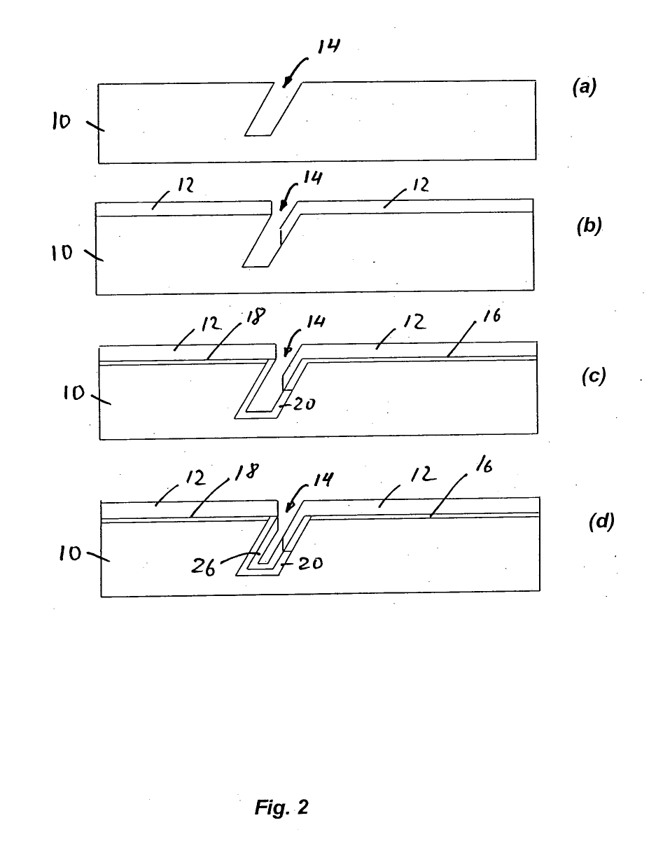

Referring now to FIG. 2, a method of selectively doping a semiconductor material for forming a solar cell according to a second specific embodiment of the present invention is now described. FIG. 2 illustrates processing steps and, if features were already illustrated in FIG. 1, uses the same reference numerals for these features as FIG. 1. In this embodiment the groove 14 is cut into the semiconductor material 10 prior to deposition of a diffusion barrier. FIG. 2 (a) shows the semiconductor material 10 with the groove 14.

An insulating layer 12, in this embodiment provided in the form of silicon nitride, is deposited using a suitable directional deposition process. FIG. 2 (b) shows the semiconductor substrate 10 with groove 14 and the electrically insulating layer 12.

The electrically insulating layer 12 is selected so that the material of the layer 12 is semi-permeable for a dopant material. Doping is then conducted so that the interior surface portion of the groove 14, which is free from the silicon nitride material, is heavily doped (region 20) and regions 16 and 18 are only lightly doped (see FIG. 2 (c)). The doping process itself is conducted in the same manner as described above in the context of the first specific embodiment.

FIG. 2 (d) shows the processed semiconductor material 10 which a metallic contact layer 26 being deposited at interior surface portions of the groove 14.

The method in accordance with the second specific embodiment of the present invention has advantages that are similar to those of the first specific embodiment of the present invention.

In one variation of the second specific embodiment the step of forming a diffusion barrier and forming an insulating, anti-reflective and surface passivating layer on the semiconductor material 10 are combined, which further increases the production efficiency. In this case the layer 12 is arranged so that it has the desired semi-permeable properties for the dopant material and at the same time the desired anti-reflective and surface passivating properties.

In an alternative variation of the second specific embodiment a further layer of insulating material, such as silicon nitride, is deposited over the layer 12 so that the layer 12 and the further layer together have the desired properties. Further, the layer 12 may also be removed after doping and replaced by a suitable layer.

Although the invention has been described with reference to particular examples, it will be appreciated by those skilled in the art that the invention may be embodied in many other forms.

1. A method of selectively doping a semiconductor material for fabricating a solar cell, the method comprising the steps of:
forming at least one angled groove in the semiconductor material;
forming a diffusion barrier on the semiconductor material, the diffusion barrier comprising a diffusion barrier material that is selected so that diffusing of a dopant material through the diffusion barrier is reduced; and thereafter
doping the semiconductor material by exposing the semiconductor material with the at least one groove to the dopant material in a manner such that a region of the semiconductor material that is covered by the diffusion barrier has a predetermined first dopant concentration; and thereafter
forming an electrical contact within the at least one angled groove;
wherein the method is conducted so that at least a portion of a surface area of the semiconductor material within the at least one groove and below the electrical contact has a second dopant concentration that is higher than the first dopant concentration.

2. The method of claim 1 wherein the step of doping the semiconductor material with the at least one groove is conducted so that a selective emitter is formed in a single doping step.

3. The method of claim 1 wherein the at least one angled groove is sufficiently angled and the electrical contact is formed so that at least a portion of the electrical contact is hidden by a portion of the semiconductor material.

4. The method of claim 1 wherein the at least one angled groove is formed so that, prior to forming the electrical contact, the semiconductor material overhangs a portion of the groove at an edge of the semiconductor material at the at least one angled groove.

5. The method of claim 1 wherein semiconductor material overhangs a majority of the surface of the at least one groove.

6. The method of claim 1 wherein the step of forming the electrical contact comprises forming at least a portion of the electrical contact at the surface area at which the at least one angled groove is substantially free of the electrically insulating material.

7. The method of claim 1 wherein the step of forming at least one angled groove comprises forming a plurality of parallel angled grooves.

8. The method of claim 1 comprising forming a layer of an electrically insulating material on the semiconductor material in a manner such that a portion of the surface area of the semiconductor material within the at least one angled groove is substantially free from the electrically insulating material.

9. The method of claim 8 wherein the step of forming the layer of an electrically insulating material comprises forming the layer by a directional deposition process.

10. The method of claim 1 wherein the diffusion barrier is removed after doping and a layer of an electrically insulating material is formed on the semiconductor material in a manner such that a portion of the surface area of the semiconductor material within the at least one angled groove or the electrical contact is substantially free from the electrically insulating material.

11. The method of claim 1 wherein the diffusion barrier is not removed and a layer of an electrically insulating material is formed on the semiconductor material in a manner such that a portion of the surface area of the semiconductor material within the at least one angled groove or the electrical contact is substantially free from the electrically insulating material.

12. The method of claim 1 wherein the at least one angled groove is formed after formation of the diffusion barrier so that the at least one angled groove cuts through the diffusion barrier and consequently a surface area of the semiconductor material within the at least one groove is then substantially free from the diffusion barrier material.

13. The method of claim 1 wherein the at least one angled groove is formed prior to the diffusion barrier and wherein the at least one angled groove is shaped and the doping is conducted so that a portion of the surface area of the semiconductor material within the at least one angled groove is substantially free from diffusion barrier material and has a second dopant concentration that is higher than the first dopant concentration.

14. The method of claim 1 wherein the diffusion barrier is formed using a directional deposition process.

15. The method of claim 13 wherein the diffusion barrier material is selected to provide desired anti-reflective and/or surface passivating properties so that there is no need for depositing a further layer having such properties.

16. The method of claim 14 wherein the diffusion barrier material is selected to provide desired anti-reflective and/or surface passivating properties so that there is no need for depositing a further layer having such properties.
